(19) United States
(12) Patent Application Publication
(10) Pub. No.: US 2003/0025574 A1
(43) Pub. Date: Feb. 6, 2003

(54) Integrated dual frequency noise attenuator and transient suppressor

(75) Inventors: John Barris, Hopkinton, MA (US); Jeff Cain, Santa Clara, CA (US); Wilson Hayworth, Blowing Rock, NC (US)

Correspondence Address: DORITY & MANNING, P.A., POST OFFICE BOX 1449, GREENVILLE, SC, 29602-1449, US

(73) Assignee: AVX CORPORATION

(21) Appl. No.: 09/920,352

(22) Filed: Aug. 1, 2001

(51) Int. Cl. H03H 7/00

(52) U.S. Cl. 333/174

(57) ABSTRACT

An integral dual frequency by-pass and transient suppressor device has at least two ceramic semiconductor layers, the upper surfaces of which are formed with electrodes of generally U-shaped configuration. The base portions of the electrodes are exposed at opposite surfaces of the semiconductor layers, the leg portions of the U-shaped electrodes extending toward the base portions of electrodes of opposite polarity. The overlap or registration area of one pair of legs differs from the overlap area of the other leg pair with the result that two capacitors of different values are formed, the capacitors being in parallel and accordingly defining a low impedance path at two discrete frequencies. By varying the conductive paths as a function of the length of the electrode and/or the base of the U, a desired internal inductance is developed. Use of a semiconductor material in place of a dielectric provides transient energy suppression by shunting to ground any signal introduced to the device at a level at or above the breakdown voltage of the semiconductor.

### BACKGROUND OF THE INVENTION

1. Field of the Invention

The present invention is directed to a by-pass or attenuator device with varistor properties and more specifically to a miniaturized ceramic device intended to attenuate noise at a plurality(at least two) discrete frequencies and provide transient suppression of voltage and current spikes. Without limitation, a particular utility of the device is as a noise attenuator and varistor in so-called dual mode cellular phones having both a digital and an analog output. In devices of this sort, where transmission is effected simultaneously on two discrete frequencies, it is desirable to minimize the “noise” generated by each of the two frequencies while protecting the circuitry from voltage and current spikes arising from external sources such as electrostatic discharge or internal sources such as battery spikes.

2. Prior Art

Conventional practice in respect of the recently developed dual mode cellular phones is to provide discrete LC networks tailored to attenuate (shunt to ground) the noise generated in the respective digital and analog transmission circuits. With the current trend to miniaturization, the requirement of utilizing discrete components to be attached to the motherboard is undesirable in that the multiple components occupy precious “geography.”

Perhaps, more importantly, in the ultra high frequencies involved in cellular technology (for example, 900 MHz for analog transmissions and 1.9 GHz for digital transmissions) the inclusion of lead paths to the respective separate components results in a great variation in inductances, since the lead paths themselves function as inductors.

Various types of circuits are known in the prior art, with some examples as follows shown by some issued U.S. patents.

U.S. Pat. No. 5,430,601 discloses a multi-layer capacitor which includes a resistance connection.

U.S. Pat. No. 5,170,317 discloses an MLC which includes, in addition to the main electrodes, a “correction” electrode which is narrower than the major electrodes to enable the provision of a capacitor having a precise value.

U.S. Pat. No. 4,758,922 discloses a U-shaped “strip line” which functions as a resonance element (capacitor) having ground plane layers and interleaved dielectric layers.

U.S. Pat. No. 4,479,100 relates to an impedance matching network which includes a plurality of electrodes of different cross-sectional areas. The electrodes are connectable in parallel with a major electrode to provide a selected desired capacitance.

U.S. Pat. No. 4,074,340 discloses an MLC which includes adjusting electrodes extending to side surfaces of the monolith. Capacitance adjustment is effected by externally connecting or disconnecting the adjusting electrodes with the major electrodes.

U.S. Pat. Nos. 4,048,593 and 2,758,256 disclose the concept of providing a multiplicity of discrete capacitors formed on a single substrate.

U.S. Pat. No. 5,898,562, commonly owned with the subject application, discloses the concept of forming two discrete capacitors of different values within one device by providing two different overlapping areas through the use of U-shaped electrodes.

The complete disclosures of the above U.S. patents are fully incorporated herein by reference.

### SUMMARY OF THE INVENTION

The present invention is directed to a ceramic integrated dual frequency noise attenuator device providing transient energy protection. More particularly, the invention is directed to an attenuator device adapted to provide a low impedance path to ground at a plurality of discrete frequencies while being further adapted to provide protection from voltage and current spikes that may reach the device.

Still, more particularly, the invention is directed to a dual frequency by-pass device with integrated varistor properties characterized in that the same is extremely simple to manufacture and provides accurate and precisely controlled dual LC circuits.

Still, more particularly, the invention is directed to single or multilayer by-pass devices with varistor properties especially adapted for noise filtration and transient energy protection, examples of such devices comprising a pair of U-shaped electrodes in a ceramic semiconductor structure. Each of the electrodes includes a base and a pair of leg portions extending from the base. In the ceramic structure each base is disposed at a margin of its respective layer, the legs of each U being directed toward the base of the opposite U, the electrodes being disposed on the upper surface of individual layers of the ceramic semiconductor.

Additional objects and advantages of the invention are set forth in, or will be apparent to those of ordinary skill in the art from, the detailed description herein. Also, it should be further appreciated by those of ordinary skill in the art that modifications and variations to the specifically illusrated, referred and discussed features and steps hereof may be practiced in various embodiments and uses of this invention without departing from the spirit and scope thereof, by virtue of present reference thereto. Such variations may include but are not limited to, substitution of equivalent means and features, materials, or steps for those shown, referenced, or discussed, and the functional, operational, or positional reversal of various parts, features, steps, or the like.

Still further, it is to be understood that different embodiments, as well as different presently preferred embodiments, of this invention may include various combinations or configurations of presently disclosed features, steps, or elements, or their equivalents (including combinations of features or steps or configurations thereof not expressly shown in the figures or stated in the detailed description).

A characterizing feature of such exemplary device is that the overlapping area defined by one pair of legs differs from the overlapping area defined by the second pair of legs, such that two discrete capacitances are formed. The differential overlap may be achieved by one pair of legs being longer than the other pair or by one pair of overlapping legs being wider than the other pair, or by combinations of these factors.

A further characterizing feature of exemplary embodiments of the invention resides in the composite of the branches of the U coupled with the base of the U functioning as an inductor whereby the device, by the provision of the U-shaped electrode combination described, inherently provides a circuit comprised of two capacitors of different values connected in parallel, in series with a pair of inductors defined by the electrodes which also form the capacitance together with the base portions of the U configurations. Where the differential capacitance is provided by the overlapping legs being longer on one side of the U than the legs of the opposite side of the U, there will inherently be provided a proportionately greater inductance due to the longer conductive path of the longer legs.

A further feature of the invention resides in the ability, due to the U-shaped configuration of the electrodes, to increase the inductance by elongating the base of the U, whereby it is feasible to separately provide an increased inductance without materially increasing the capacitance.

A further characterizing feature of exemplary embodiments of the device resides in the semiconductor material used in place of the dielectric otherwise heretofore used to construct capacitors, the semiconductor material having dielectric properties that allow the device to function as a capacitor at voltage levels below the breakdown voltage of the semiconductor material as well as conductive properties at voltage levels at or above the breakdown voltage of the semiconductor that allow the device to function as a varistor.

The device of the invention provides a compact and readily manufactured component providing optimal by-pass and noise reduction as well as varistor properties in a single chip having but two leads(surface-mount or wire) to be connected to the motherboard. By minimizing the external conductive path, a great degree of control of the characteristics of the by-pass device is achieved. This is in contrast to bypass techniques employing discrete capacitors and inductors which inherently require elongated conductive paths on the PC board and, hence, greater and less controlled inductances.

In accordance with the invention it is an object to provide a readily manufactured integral chip device especially adapted to function as a by-pass or noise reducing device for a plurality of discrete frequencies while simultaneously functioning as a varistor for protecting the circuit from voltage and current spikes.

A further object of the invention is the provision of a device of the class described wherein the capacitive and inductive values may be precisely determined, the device being compatible with the desired highly efficient use of the geography of an associated motherboard.

A further aspect of the invention is directed to the integration of a dual frequency noise attenuator device with the transient energy protection characteristics of a varistor. The protection characteristics of a varistor are achieved through the use of a semiconductor such as zinc oxide(ZnO) in place of the dielectric otherwise used to construct capacitors.

Additional embodiments of the subject invention, not necessarily expressed in this summarized section, may include and incorporate various mixtures and combinations of aspects of features referenced in the summarized objectives above, and/or other features as otherwise discussed in this application.

Those of ordinary skill in the art will better appreciate the features and aspects of such embodiments, including methodologies, and others, upon review of the remainder of the specification.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a representative exploded perspective view of an exemplary device of the invention.

FIGS. 2 and 3 are respectively plan views of the top and bottom electrodes of an exemplary device in accordance with the invention.

FIG. 4 is a diagram of the circuitry defined by the exemplary device of the invention as represented in present FIG. 1.

FIGS. 5 and 6 are respectively plan views of the top and bottom electrodes of an exemplary device of the invention discussed in detail below.

FIGS. 7 and 8 are respectively plan views of the top and bottom electrodes as placed relative to an exemplary device shown with specific locations for certain dimensions for the exemplary device discussed in accordance with the invention discussed in conjunction with FIGS. 5 and 6.

FIG. 9 is a schematic exploded perspective view of the exemplary device of the invention as discussed in conjunction with FIGS. 5 through 8.

FIG. 10 is a diagram of the circuitry defined by the exemplary device of the invention as discussed in conjunction with FIGS. 5 through 9.

FIG. 11 is a graph showing the attenuation versus frequency for the exemplary device of the invention as discussed in conjunction with FIGS. 5 through 10.

Repeat use of reference characters is intended to represent same or analogous features or elements of the subject invention. The figures are not necessarily drawn to scale and in some instances have been enlarged in pertinent part to illustrate detail for better visualization and understanding of the invention.

### DETAILED DESCRIPTION OF PREFERRED EMBODIMENTS

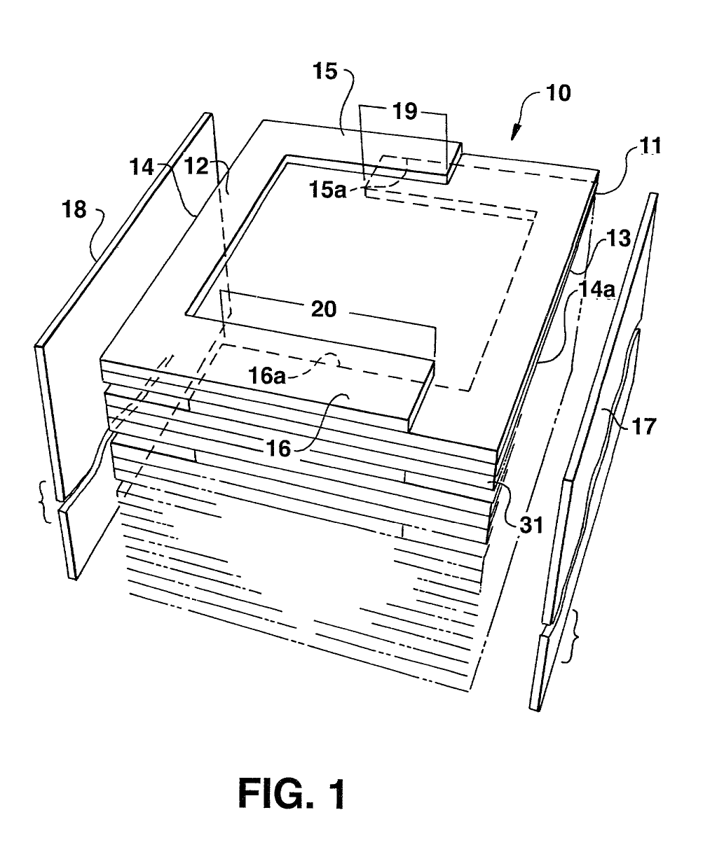

Referring now to the drawings, there is shown in FIG. 1 a representative exploded perspective of a device in accordance with the invention, the dimension and thickness of the various elements being greatly increased to facilitate visualization and understanding of the structure.

The by-pass varistor device generally 10 is comprised of at least two semiconductor layers 11 and 31, the upper surfaces of which have formed thereon U-shaped upper and lower electrodes 12 and 13. Electrode 12 includes a base portion 14 having legs 15 and 16 projecting from the opposite ends. Electrode 13 includes a base portion 14a from the opposite ends of which project leg portions 15a and 16a.

As best seen in FIG. 1 electrodes 12 and 13 are disposed respectively above semiconductor layers 11 and 31 in such manner that the respective base portions 14,14a are exposed at opposite edges of the semiconductor layers. As will be appreciated from FIG. 1 wherein a single unit comprised of upper and lower electrodes and an intervening semiconductor layer are shown in solid lines, any number of layers may be formed in the multi-layer device to achieve the desired values of capacitance and inductance.

Terminations 17,18 are formed at the end margins of the semiconductor layers, the termination 17 being electrically coupled to the base portions 14a of the electrodes 13 and termination 18 being electrically coupled to the base portion or portions of electrodes 12.

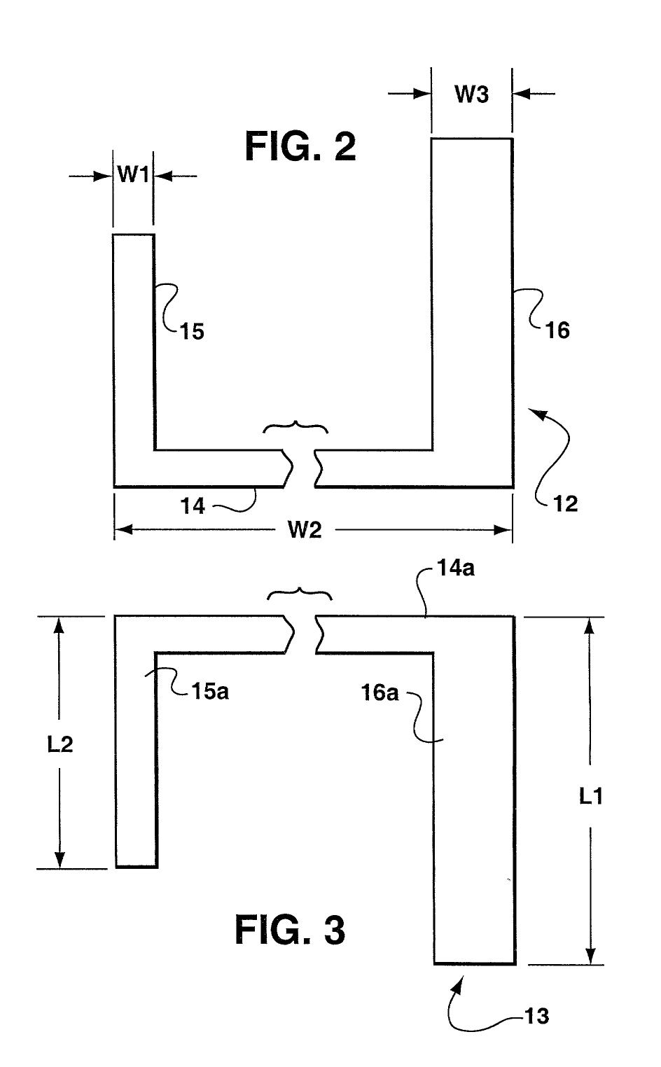

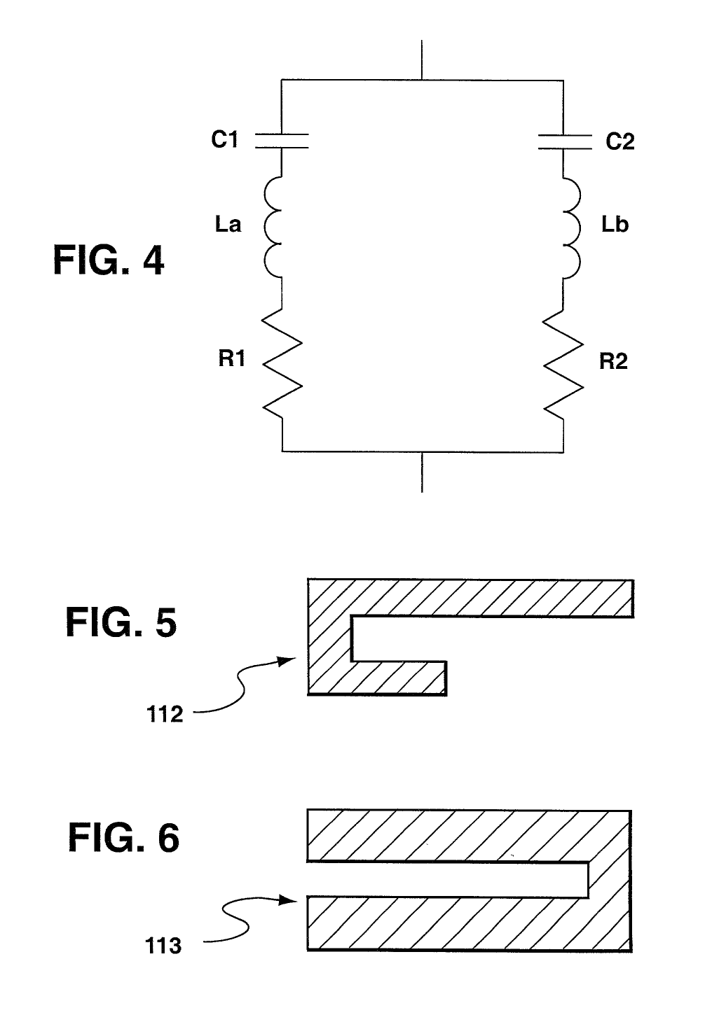

As is evident from FIGS. 1 through 3, due to the smaller width and lengths L2 of legs 15 and 15a, the registering or overlapping area 19 defined by the legs 15,15a will be less than the overlapping area 20 defined by longer and wider legs 16,16a whose length is represented by the notation L1.

The capacitance defined in the area 19 will be less than the capacitance defined in the area 20, since capacitance is directly proportional to the areas of overlap. It will thus be appreciated that the desired capacitive differential between capacitor C1 defined by overlapping areas 19 from the larger capacitance C2 defined by overlapping areas 20 can be achieved by varying the width of the respective overlapping leg components or by varying the length of the overlapping components or by both expedients.

Particularly desirable is adjusting capacitance in accordance with the length of the overlapping legs, since the inductance provided is a function of the entire length of the conductive path and thus by utilizing legs of different lengths there is inherently provided a larger inductance where the leg lengths are longer whereby the inductance value is automatically greater to interact with the larger capacitance.

The semiconductor 11 interleaved between upper and lower electrodes 12 and 13 has all of the requisite electrical insulative characteristics of a dielectric for the creation of a capacitance when integrated into the aforesaid dual frequency noise attenuator. However, the use of a semiconductor in place of the typically used dielectric provides other useful qualities to the integrated device.

The use of a semiconductor in the place of the dielectric allows the device to further function as a varistor. As will be appreciated, a semiconductor begins to conduct at a particular breakdown voltage. If a voltage level at or above the breakdown voltage level of the semiconductor is introduced into the dual resonant capacitor device, the semiconductor will begin to conduct and effectively shunt the undesired signal to ground. Thus, the device will now protect the circuitry from voltage and current spikes that can commonly occur as a result of events such as electrostatic discharge (ESD) or battery spikes. The integration of these functions into one device is very desirable in the electronics industry as the trend toward miniaturization continues.

### Methodology

The manner of fabrication of the by-pass device with varistor properties is mostly the same as the conventional methods of fabricating ceramic capacitors. Since this methodology is well known to those skilled in the art it will be merely briefly described below. It will also be apparent to those skilled in the art that this is only one of many commonly known methods of fabricating ceramic capacitors.

The semiconductor components are formed by casting a thin layer of a slurry of finely divided semiconductor forming material such as zinc oxide suspended in a liquid matrix including binder. The “green” ceramic is screen printed with electrode forming ink in the desired U-shaped patterns. Typically, the ink will include a metal, such as platinum. Patterned green ceramics are superposed to provide the desired number of layers, the patterns of adjacent layers being coordinated to achieve the desired overlapped condition. Individual units are diced from the superposed layers in such manner as to expose base portions 14,14a at opposite ends of the pre-fired chips. The diced units are thereafter subjected to binder burn-off at a first temperature and thereafter sintered at a higher temperature to define the structure.

Terminations 17,18 are applied to the respective exposed base portions 14 at one end and 14a at the other end. Terminations may be formed in any of a number of known manners including vapor deposition to provide electrical and mechanical bond to the exposed electrode bases at opposite ends of the semiconductor layers followed by application of one or more metallic layers over the sputtered layer to enable soldering to the motherboard. The terminations may extend beyond the end margins where suface mounting is desired. Alternative termination methods include applications of carbon followed by an outer silver layer with or without intervening metallic layers between carbon and silver.

### EXAMPLE

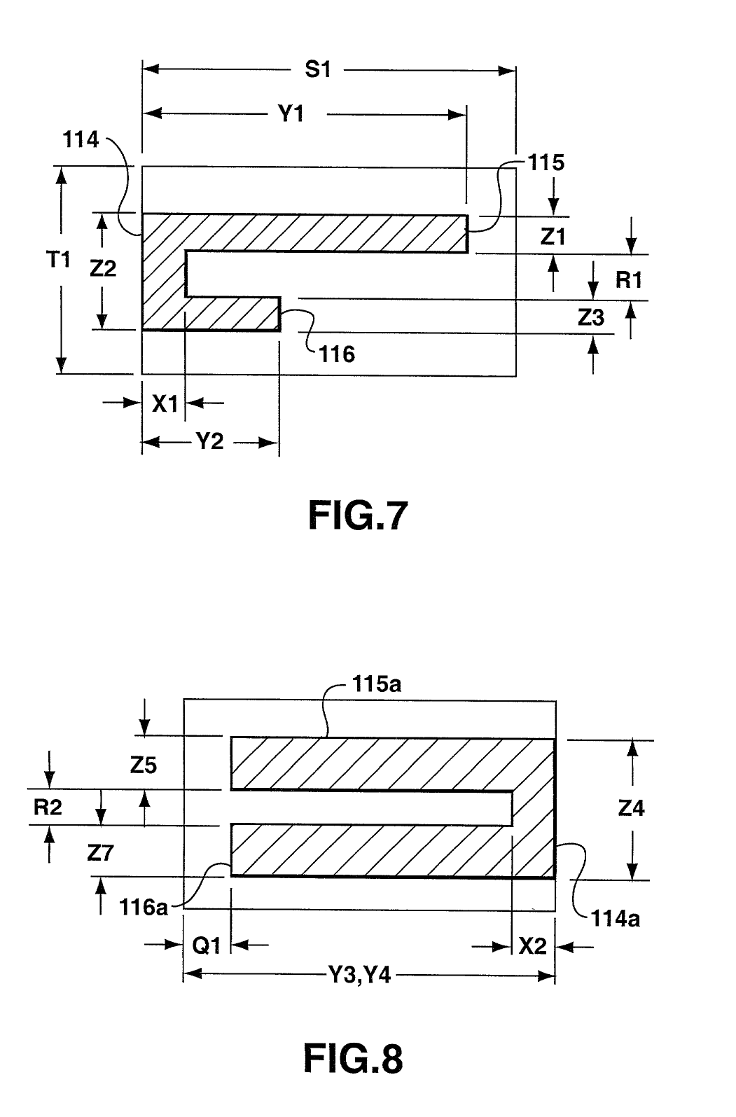

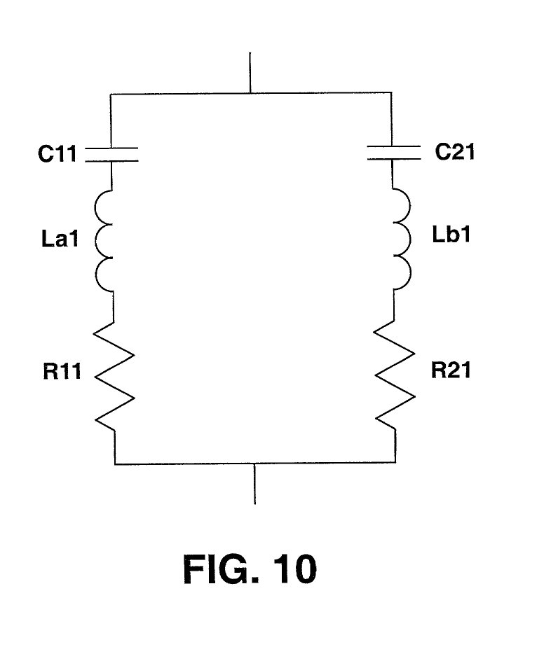

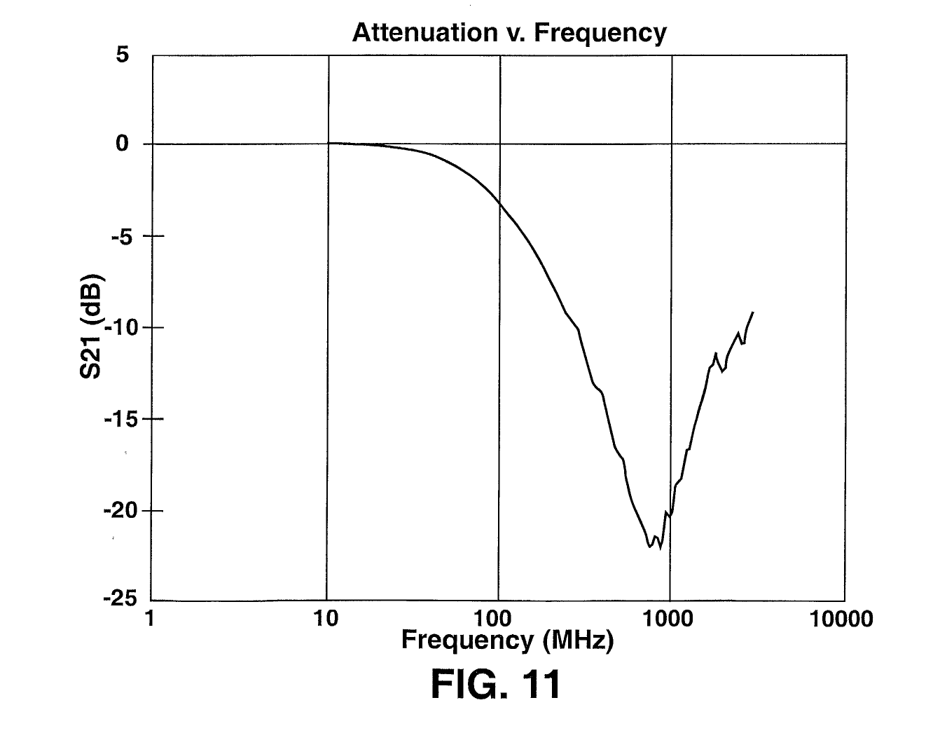

Without limitation, and in compliance with the “best mode” requirements of the patent laws of the United States, a specific example of an assembly in accordance with the invention is provided below, with reference to FIGS. 5 through 10. Those of ordinary skill in the art will appreciate that other exemplary embodiments of the subject invention may have other component values and dimensions.

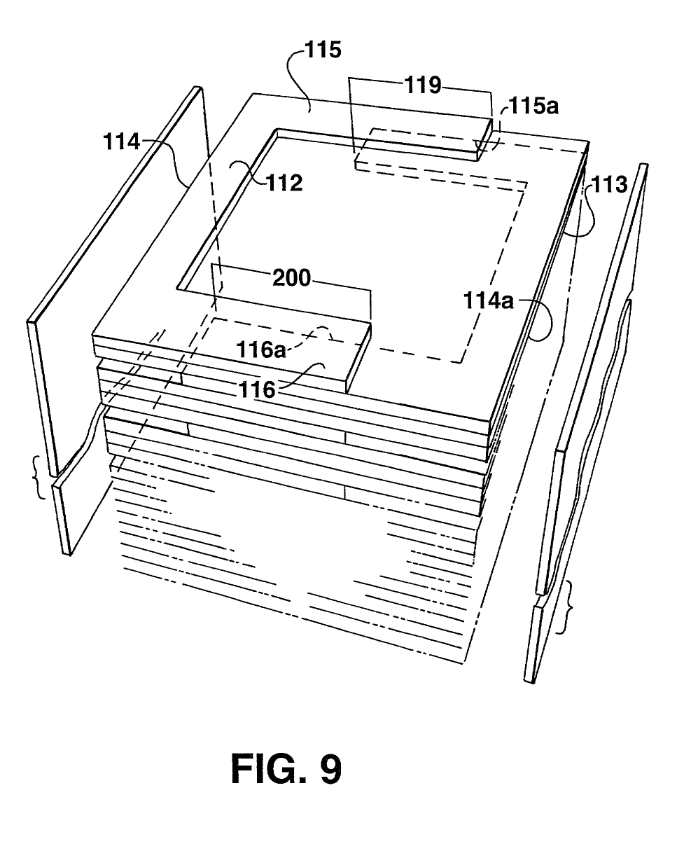

A multi-layer device is formed utilizing 8 active layers of a zinc oxide ceramic approximately 0.002268 inches thick. In such example, 8 active electrodes are employed. In the example provided, the widths Z1 and Z3 of the legs 115 and 116, respectively, are identical and comprise 0.004860 inches. The widths Z5 and Z7 of the legs 115a and 116a, respectively, are identical and comprise 0.007290 inches. The length Z2 of the base portion 114 is 0.01620 inches. The length Z4 of the base portion 114a is 0.019440 inches. The length Y1 of leg 115 is 0.029970 inches. The length Y2 of leg 116 is 0.01701 inches. The lengths Y3 and Y4 of legs 115a and 116a are identical and comprise 0.050220 inches. The widths X1 and X2 of branches 114 and 114a are identical and comprise 0.006480 inches. The distance R1 between legs 115 and 116 is 0.006480 inches. The distance R2 between legs 115a and 116a is 0.004860 inches. The overall length S1 of each layer is 0.059940 inches. The overall width T1 of each layer is 0.03240 inches. The distance Q1 between the end of legs 115a and 116a and the outer edge of the layer is 0.009720 inches. As best seen in FIG. 9, the electrodes are stacked such that the overlap or registering area 119 of legs 115 and 115a is approximately three times the overlap area 200 of legs 116 and 116a.

The capacitance values were tested with the capacitance C11 defined by overlap area 200 being approximately 16 picofarad and the capacitance C21 defined by area 119 being approximately 46 picofarad. Inductances La1 and Lb1 were calculated to be approximately 0.6 nanohenry.

Obviously, by tailoring the overlap area a wide diversity of capacitor values may be achieved. Similarly, by modifying the length and the width of the electrode legs and base, the desired inductances may be tailored to fit specific situations. The representative resistive values R11 and R21 associated with these devices are nominal and are inherently dependent upon the device's physical construction and specific examples thereof are not important to the discussion of the exemplary embodiment herein. The values of the illustrated example have been found highly efficient as by-pass devices for dual mode cellular phones operating on respective analog and digital frequencies of 900 MHz and 1.9 GHz. Of particular advantage is the predictable nature of the inductance as contrasted with the large variations resulting from the utilization of separate capacitors with the attendant variations in path lengths of the leads between the capacitors.

As will be apparent to those skilled in the art who have been familiarized with the instant disclosure, numerous variations in details of construction may be derived without departing from the spirit of the invention. Accordingly, the invention is to be broadly construed.

What is claimed is:

1. A multi-frequency noise attenuation device with varistor characteristics and having a first and a second side, said device comprising a plurality of three-layer LC circuit stacks interdigitated with an equal plurality of secondary semiconductor layers.

2. A multi-frequency noise attenuation device with varistor characteristics as in claim 1, said three-layer LC circuit stack further comprising:
a first U-shaped ceramic electrode plate having a first base portion and variable length and variable width first leg portions, said first base portion lying along said device's first side;
a primary semiconductor layer;
a second U-shaped ceramic electrode plate having a second base portion and variable length and variable width second leg portions, said second base portion lying along said device's second side; and
wherein said first and said second sides oppose each other.

3. A multi-frequency noise attenuation device with varistor characteristics as in claim 2, said device further comprising:
a first termination electrically connected to said first base portions of said first U-shaped ceramic electrode plates; and
a second termination electrically connected to said second base portions of said second U-shaped ceramic electrode plates.

4. A multi-frequency noise attenuation device with varistor characteristics as in claim 2, wherein said first leg portions and said second leg portions within each three-layer LC circuit stack overlap lengthwise by a predetermined amount.

5. A multi-frequency noise attenuation device with varistor characteristics as in claim 4, wherein said first and second leg portion's area of overlap within each three-layer LC circuit stack is predetermined so as to precisely define the resulting paired capacitance values.

6. A multi-frequency noise attenuation device with varistor characteristics as in claim 2, wherein said primary and said secondary semiconductor layers comprise a zinc oxide material.

7. A multi-frequency noise attenuation device with varistor characteristics and having a first and a second side, said device comprising a plurality of four-layer LC circuit stacks.

8. A multi-frequency noise attenuation device with varistor characteristics, as in claim 7, said four-layer LC circuit stack further comprising:
a first U-shaped ceramic electrode plate having a first base portion and variable length and variable width first leg portions, said first base portion lying along said device's first side;
a first semiconductor layer;
a second U-shaped ceramic electrode plate having a second base portion and variable length and variable width second leg portions, said second base portion lying along said device's second side;
a second semiconductor layer; and
wherein said first and said second sides oppose each other.

9. A multi-frequency noise attenuation device with varistor characteristics, as in claim 8, said device comprising:
a first termination electrically connected to said first base portions of said first U-shaped ceramic electrode plates; and
a second termination electrically connected to said second base portions of said second U-shaped ceramic electrode plates.

10. A multi-frequency noise attenuation device with varistor characteristics as in claim 2, wherein said first leg portions and said second leg portions within each three-layer LC circuit stack overlap lengthwise by a predetermined amount.

11. A multi-frequency noise attenuation device with varistor characteristics as in claim 10, wherein said first and second leg portion's area of overlap within each three-layer LC circuit stack is predetermined so as to precisely define the resulting paired capacitance values.

12. A multi-frequency noise attenuation device with varistor characteristics as in claim 8, wherein said primary and said secondary semiconductor layers comprise a zinc oxide material.

13. A multi-frequency noise attenuation device with varistor characteristics and having a first and a second side, said device comprising:
a first U-shaped electrode plate;
a second U-shaped ceramic electrode plate; and
a plurality of semiconductor layers.

14. A multi-frequency noise attenuation device with varistor characteristics as in claim 13, wherein said plurality of semiconductor layers is interdigitated with said first and said second U-shaped electrode plates.

15. A multi-frequency noise attenuation device with varistor characteristics as in claim 14, said first U-shaped electrode plate further comprising:
a first base portion lying along said device's first side;
a first leg portion;
a second leg portion; and
wherein said first and second leg portions have predefined variable length and width characteristics relative to each other.

16. A multi-frequency noise attenuation device with varistor characteristics as in claim 15, said second U-shaped electrode plate further comprising:
a second base portion lying along said device's second side;
a third leg portion;
a fourth leg portion; and
wherein said third and fourth leg portions have predefined variable length and width characteristics relative to each other.

17. A multi-frequency noise attenuation device with varistor characteristics as in claim 16, wherein said first and said third leg portions define a first area of overlap and said second and said fourth leg portions define a second area of overlap.

18. A multi-frequency noise attenuation device with varistor characteristics as in claim 19, wherein said first and second areas of overlap are of differing values.

19. A multi-frequency noise attenuation device with varistor characteristics as in claim 16, said device further comprising:
a first termination electrically connected to said first base portion of said first U-shaped ceramic electrode plate;
a second termination electrically connected to said second base portion of said second U-shaped ceramic electrode plate; and
wherein said first and said second sides oppose each other.

20. A multi-frequency noise attenuation device with varistor characteristics as in claim 13, wherein said plurality of semiconductor layers comprise a zinc oxide material.

21. A multi-frequency noise attenuation device with varistor characteristics as in claim 13, wherein said first and said second U-shaped electrode plates are ceramic.

22. A method of manufacturing a multi-frequency noise attenuation device with varistor characteristics, said method comprising the steps of:
(a) providing a plurality of primary semiconductive layers;
(b) providing a plurality of secondary semiconductive layers;
(c) screen-printing on each of said plurality of primary semiconductive layers a first ceramic U-shaped electrode plate;
(d) screen-printing on each of said plurality of secondary semiconductive layers a second ceramic U-shaped electrode plate;
(e) interdigitating said primary and secondary semiconductive layers with said first and said second U-shaped electrode plates thereon; and
(f) providing opposing polarity terminations to said device so as to have a first termination electrically connected to said first ceramic U-shaped electrode plates and the opposing second termination electrically connected to said second ceramic U-shaped electrode plates.

23. A method of manufacturing a multi-frequency noise attenuation device with varistor characteristics as in claim 22, wherein said device has a first side and a second side which oppose each other and wherein said first U-shaped electrode plate has a base potion which lies along said first side in electrical communication with said first termination and said second U-shaped electrode plate has a second base portion which lies along said second side in electrical communication with said second termination.

24. A method of manufacturing a multi-frequency noise attenuation device with varistor characteristics as in claim 23, wherein said first U-shaped electrode plate has two leg portions and said second U-shaped electrode plate has two leg portions and wherein said first electrode plate's two leg portions overlap said second electrode's two leg portions to form capacitor elements in an LC circuit.
